(19) United States
(12) Patent Application Publication
(10) Pub. No.: US 2024/0287859 A1
(43) Pub. Date: Aug. 29, 2024

(54) AUTOMATED DECISION-MAKING AND LEARNING TECHNIQUES WITH HETEROGENEOUS SIMULATORS IN COILED TUBING OPERATIONS

(71) Applicant: SCHLUMBERGER TECHNOLOGY CORPORATION, Sugar Land, TX (US)

(72) Inventors: Filip DVORAK, Houston, TX (US); Vassilis VARVEROPOULOS, Katy, TX (US); Philippe Michel Jacques TARDY, Houston, TX (US); Jordi Juan SEGURA DOMINGUEZ, Tananger (NO); Tianxiang SU, Arlington, MA (US); Laurence Cathy FOSSATI, Houston, TX (US); Stephane GEORGET, Caours (FR)

(21) Appl. No.: 18/572,457

(22) PCT Filed: Jun. 20, 2022
(86) PCT No.: PCT/US2022/034167

§ 371 Date: Dec. 20, 2023

Related U.S. Application Data
(60) Provisional application No. 63/212,922, filed on Jun. 21, 2021.

(51) Int. Cl. E21B 19/22; G06F 30/28

(52) U.S. Cl. CPC E21B 19/22; G06F 30/28; E21B 2200/20

(57) ABSTRACT

Systems and methods presented herein facilitate coiled tubing operations, and generally relate to coiled tubing simulators that capture decades of expertise. In particular, the various simulators are formulated as a simulator graph search problem that enables optimal querying of the simulators (e.g., maximizing confidence and efficiency). The representation for a simulator graph is built and integrated with AI planning, constraint satisfaction programming (CSP), reinforcement learning (RL), and execution, which includes three main steps: (1) creation of a simulator graph that encodes the relations between inputs and outputs of different simulators. (2) integration of the simulator graph with an AI planner, CSP and RL, and (3) plan execution and monitoring of the plan with dynamic re-planning, as needed.

### CROSS-REFERENCE TO RELATED APPLICATION

This application claims priority to and the benefit of U.S. Provisional Patent Application Ser. No. 63/212,922, entitled “Automated Decision-Making and Learning Techniques with Heterogeneous Simulators in Coiled Tubing Operations,” filed Jun. 21, 2021, which is hereby incorporated by reference in its entirety for all purposes.

### BACKGROUND

The present disclosure generally relates to automated decision-making and learning techniques with heterogeneous simulators in coiled tubing operations. This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as an admission of any kind.

In many well applications, coiled tubing is employed to facilitate performance of many types of downhole operations. Coiled tubing offers versatile technology due in part to its ability to pass through completion tubulars while conveying a wide array of tools downhole. A coiled tubing system may comprise many systems and components, including a coiled tubing reel, an injector head, a gooseneck, lifting equipment (e.g., a mast or a crane), and other supporting equipment such as pumps, treating irons, or other components. Coiled tubing has been utilized for performing well treatment and/or well intervention operations in existing wellbores such as hydraulic fracturing operations, matrix acidizing operations, milling operations, perforating operations, coiled tubing drilling operations, and various other types of operations.

### SUMMARY

A summary of certain embodiments described herein is set forth below. It should be understood that these aspects are presented merely to provide the reader with a brief summary of these certain embodiments and that these aspects are not intended to limit the scope of this disclosure.

Certain embodiments of the present disclosure include a method that includes creating, via a processing system, a simulator graph that encodes one or more relationships between inputs and outputs of a plurality of heterogeneous physics models relating to running a downhole well tool into a wellbore via coiled tubing. The method also includes integrating, via the processing system, the simulator graph with one or more processing modules configured to develop one or more plans relating to running the downhole well tool into the wellbore via the coiled tubing. The method further includes executing, via the processing system, the one or more processing modules to develop the one or more plans relating to running the downhole well tool into the wellbore via the coiled tubing. In addition, the method includes monitoring, via the processing system, execution of the one or more plans relating to running the downhole well tool into the wellbore via the coiled tubing.

Certain embodiments of the present disclosure also include a tangible non-transitory computer-readable media comprising process-executable instructions that, when executed by one or more processors, cause the one or more processors to create a simulator graph that encodes one or more relationships between inputs and outputs of a plurality of heterogeneous physics models relating to running a downhole well tool into a wellbore via coiled tubing, to integrate the simulator graph with one or more processing modules configured to develop one or more plans relating to running the downhole well tool into the wellbore via the coiled tubing, to execute the one or more processing modules to develop the one or more plans relating to running the downhole well tool into the wellbore via the coiled tubing, and to monitor execution of the one or more plans relating to running the downhole well tool into the wellbore via the coiled tubing.

Certain embodiments of the present disclosure also include a system that includes a surface processing system configured to create a simulator graph that encodes one or more relationships between inputs and outputs of a plurality of heterogeneous physics models relating to running a downhole well tool into a wellbore via coiled tubing, to integrate the simulator graph with one or more processing modules configured to develop one or more plans relating to running the downhole well tool into the wellbore via the coiled tubing, to execute the one or more processing modules to develop the one or more plans relating to running the downhole well tool into the wellbore via the coiled tubing, and to monitor execution of the one or more plans relating to running the downhole well tool into the wellbore via the coiled tubing.

Various refinements of the features noted above may be undertaken in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings, in which:

FIG. 1 is a schematic illustration of a well system that obtains sensor data to dynamically update information related to operation and control of a downhole well tool, in accordance with embodiments of the present disclosure;

FIG. 2 illustrates a well control system that may include a surface processing system to control the well system described herein, in accordance with embodiments of the present disclosure;

FIG. 3 illustrates an example simulator graph with variables x, y, and z and two simulators-a flow simulator and a weight simulator, in accordance with embodiments of the present disclosure;

FIG. 4 illustrates example steps for training using reinforcement learning, in accordance with embodiments of the present disclosure; and

FIG. 5 illustrates an exemplary process of executing, monitoring, and re-planning, in accordance with embodiments of the present disclosure.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “connect,” “connection,” “connected,” “in connection with,” and “connecting” are used to mean “in direct connection with” or “in connection with via one or more elements”; and the term “set” is used to mean “one element” or “more than one element.” Further, the terms “couple,” “coupling,” “coupled,” “coupled together,” and “coupled with” are used to mean “directly coupled together” or “coupled together via one or more elements.” As used herein, the terms “up” and “down,” “uphole” and “downhole”, “upper” and “lower,” “top” and “bottom,” and other like terms indicating relative positions to a given point or element are utilized to more clearly describe some elements. Commonly, these terms relate to a reference point as the surface from which drilling operations are initiated as being the top (e.g., uphole or upper) point and the total depth along the drilling axis being the lowest (e.g., downhole or lower) point, whether the well (e.g., wellbore, borehole) is vertical, horizontal or slanted relative to the surface.

As used herein, a fracture shall be understood as one or more cracks or surfaces of breakage within rock. Fractures can enhance permeability of rocks greatly by connecting pores together and, for that reason, fractures can be induced mechanically in some reservoirs in order to boost hydrocarbon flow. Certain fractures may also be referred to as natural fractures to distinguish them from fractures induced as part of a reservoir stimulation. Fractures can also be grouped into fracture clusters (or “perf clusters”) where the fractures of a given fracture cluster (perf cluster) connect to the wellbore through a single perforated zone. As used herein, the term “fracturing” refers to the process and methods of breaking down a geological formation and creating a fracture (i.e., the rock formation around a well bore) by pumping fluid at relatively high pressures (e.g., pressure above the determined closure pressure of the formation) in order to increase production rates from a hydrocarbon reservoir.

In addition, as used herein, the terms “real time”, “real-time”, or “substantially real time” may be used interchangeably and are intended to described operations (e.g., computing operations) that are performed without any human-perceivable interruption between operations. For example, as used herein, data relating to the systems described herein may be collected, transmitted, and/or used in control computations in “substantially real time” such that data readings, data transfers, and/or data processing steps occur once every second, once every 0.1 second, once every 0.01 second, or even more frequent, during operations of the systems (e.g., while the systems are operating). In addition, as used herein, the terms “automatic” and “automated” are intended to describe operations that are performed are caused to be performed, for example, by a processing system (i.e., solely by the processing system, without human intervention).

The embodiments described herein generally include systems and methods that facilitate operation of well-related tools. In certain embodiments, a variety of data (e.g., downhole data and/or surface data) may be collected to enable optimization of operations related to the well-related tools. In certain embodiments, the collected data may be provided as advisory data (e.g., presented to human operators of the well to inform control actions performed by the human operators) and/or used to facilitate automation of downhole processes and/or surface processes (e.g., which may be automatically performed by a computer implemented surface processing system (e.g., a well control system), without intervention from human operators). In certain embodiments, the systems and methods described herein may enhance downhole operations by improving the efficiency and utilization of data to enable performance optimization and improved resource controls of the downhole operations. In certain embodiments, a downhole well tool may be deployed downhole into a wellbore via coiled tubing. In certain embodiments, the systems and methods described herein may be used for displaying or otherwise outputting desired (e.g., optimal) actions to human operators so as to enable improved decision-making regarding operation of the well tool (e.g., operation of a downhole or surface system/device).

In certain embodiments, downhole parameters are obtained via, for example, downhole sensors while the downhole well tool is disposed in the wellbore. In certain embodiments, the downhole parameters may be obtained by the downhole sensors in substantially real time (e.g., as the downhole data is detected while the downhole well tool is being operated), and sent to the surface processing system (or other suitable processing system) via wired or wireless telemetry. The downhole parameters may be combined with surface parameters. In certain embodiments, the downhole and/or surface parameters may be processed during operation of the well tool downhole to enable automatic optimization (e.g., by the surface processing system, without human intervention) with respect to the operation of the well tool during subsequent stages of well tool operation.

The embodiments described herein overcome disadvantages and shortcomings of existing systems and methods. For example, the embodiments described herein facilitate the control of downhole and surface pressures and flow rates during coiled tubing operations by, for example, orchestration of the pump and flowback controls, and further optimization via substantially real-time downhole and/or surface measurements. For example, in certain embodiments, pressure and flow rate measurements at both the pumps and flowback equipment, in addition to integrated choke control and pump controls, may be used by the surface processing system described herein (e.g., including programmable logic controllers (PLCs)).

In addition, the embodiments described herein include coiled tubing simulators that capture decades of expertise and, as such, it is desirable to capture as much information as possible from the simulators themselves, formulating the problem of querying simulators optimally (e.g., maximizing confidence and efficiency) as a simulator graph search problem, as described in greater detail herein. Consequently, the representation for a simulator graph is built and integrated with artificial intelligence (AI) planning, constraint satisfaction programming (CSP), reinforcement learning (RL), and execution, which includes three main steps: (1) creation of a simulator graph that encodes the relations between inputs and outputs of different simulators, (2) integration of the simulator graph with an AI planner, CSP and RL, and (3) plan execution and monitoring of the plan with dynamic re-planning, as needed.

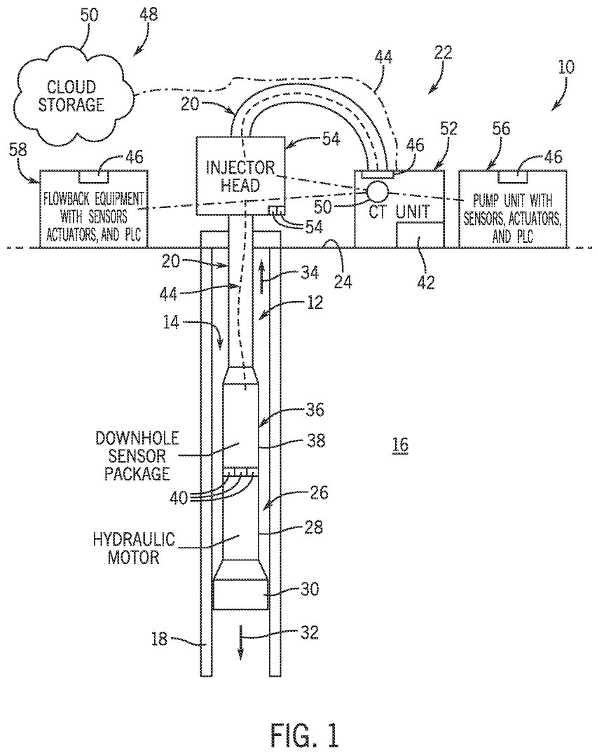

With the foregoing in mind, FIG. 1 is a schematic illustration of an example coiled tubing system 10. As illustrated, in certain embodiments, a coiled tubing string 12 may be run into a wellbore 14 that traverses a hydrocarbon-bearing reservoir 16. While certain elements of the coiled tubing system 10 are illustrated in FIG. 1, other elements of the well (e.g., blow-out preventers, wellhead “tree”, etc.) have been omitted for clarity of illustration. In certain embodiments, the coiled tubing system 10 includes an interconnection of pipes, including vertical and/or horizontal casings 18, coiled tubing 20, and so forth, that connect to a surface facility 22 at the surface 24 of the coiled tubing system 10. In certain embodiments, the coiled tubing 20 extends inside the casing 18 and terminates at a tubing head (not shown) at or near the surface 24. In addition, in certain embodiments, the casing 18 contacts the wellbore 14 and terminates at a casing head (not shown) at or near the surface 24.

In certain embodiments, a bottom hole assembly (“BHA”) 26 may be run inside the casing 18 by the coiled tubing 20. As illustrated in FIG. 1, in certain embodiments, the BHA 26 may include a downhole motor 28 that operates to rotate a drill bit 30 (e.g., during drilling operations) or other downhole tool. In certain embodiments, the downhole motor 28 may be driven by hydraulic forces carried in fluid supplied from the surface 24 of the coiled tubing system 10. In certain embodiments, the BHA 26 may be connected to the coiled tubing 20, which is used to run the BHA 26 to a desired location within the wellbore 14. It is also contemplated that, in certain embodiments, the rotary motion of the drill bit 30 may be driven by rotation of the coiled tubing 20 effectuated by a rotary table or other surface-located rotary actuator. In such embodiments, the downhole motor 28 may be omitted.

In certain embodiments, the coiled tubing 20 may also be used to deliver fluid 32 to the drill bit 30 through an interior of the coiled tubing 20 to aid in the drilling process and carry cuttings and possibly other fluid and solid components in return fluid 34 that flows up the annulus between the coiled tubing 20 and the casing 18 (or via a return flow path provided by the coiled tubing 20, in certain embodiments) for return to the surface facility 22. It is also contemplated that the return fluid 34 may include remnant proppant (e.g., sand) or possibly rock fragments that result from a hydraulic fracturing application, and flow within the coiled tubing system 10. Under certain conditions, fracturing fluid and possibly hydrocarbons (oil and/or gas), proppants and possibly rock fragments may flow from the fractured reservoir 16 through perforations in a newly opened interval and back to the surface 24 of the coiled tubing system 10 as part of the return fluid 34. In certain embodiments, the BHA 26 may be supplemented behind the rotary drill by an isolation device such as, for example, an inflatable packer that may be activated to isolate the zone below or above it, and enable local pressure tests.

As such, in certain embodiments, the coiled tubing system 10 may include a downhole well tool 36 that is moved along the wellbore 14 via the coiled tubing 20. In certain embodiments, the downhole well tool 36 may include a variety of drilling/cutting tools coupled with the coiled tubing 20 to provide a coiled tubing string 12. In the illustrated embodiment, the downhole well tool 36 includes a drill bit 30, which may be powered by a motor 28 (e.g., a positive displacement motor (PDM), or other hydraulic motor) of a BHA 26. In certain embodiments, the wellbore 14 may be an open wellbore or a cased wellbore defined by a casing 18. In addition, in certain embodiments, the wellbore 14 may be vertical or horizontal or inclined. It should be noted the downhole well tool 36 may be part of various types of BHAs 26 coupled to the coiled tubing 20.

As also illustrated in FIG. 1, in certain embodiments, the coiled tubing system 10 may include a downhole sensor package 38 having a plurality of downhole sensors 40. In certain embodiments, the sensor package 38 may be mounted along the coiled tubing string 12, although certain downhole sensors 40 may be positioned at other downhole locations in other embodiments. In certain embodiments, data from the downhole sensors 40 may be relayed uphole to a surface processing system 42 (e.g., a computer-based processing system) disposed at the surface 24 and/or other suitable location of the coiled tubing system 10. In certain embodiments, the data may be relayed uphole in substantially real time (e.g., relayed while it is detected by the downhole sensors 40 during operation of the downhole well tool 36) via a wired or wireless telemetric control line 44, and this real-time data may be referred to as edge data. In certain embodiments, the telemetric control line 44 may be in the form of an electrical line, fiber-optic line, or other suitable control line for transmitting data signals. In certain embodiments, the telemetric control line 44 may be routed along an interior of the coiled tubing 20, within a wall of the coiled tubing 20, or along an exterior of the coiled tubing 20. In addition, as described in greater detail herein, additional data (e.g., surface data) may be supplied by surface sensors 46 and/or stored in memory locations 48. By way of example, historical data and other useful data may be stored in a memory location 48 such as cloud storage 50.

As illustrated, in certain embodiments, the coiled tubing 20 may deployed by a coiled tubing unit 52 and delivered downhole via an injector head 54. In certain embodiments, the injector head 54 may be controlled to slack off or pick up on the coiled tubing 20 so as to control the tubing string weight and, thus, the weight on bit (WOB) acting on the bit of the drill bit 30 (or other downhole well tool 36). In certain embodiments, the downhole well tool 36 may be moved along the wellbore 14 via the coiled tubing 20 under control of the injector head 54 so as to apply a desired tubing weight and, thus, to achieve a desired rate of penetration (ROP) as the drill bit 30 is operated. Depending on the specifics of a given application, various types of data may be collected downhole, and transmitted to the surface processing system 42 in substantially real time to facilitate improved operation of the downhole well tool 36. For example, the data may be used to fully or partially automate the downhole operation, to optimize the downhole operation, and/or to provide more accurate predictions regarding components or aspects of the downhole operation.

In certain embodiments, fluid 32 may be delivered downhole under pressure from a pump unit 56. In certain embodiments, the fluid 32 may be delivered by the pump unit 56 through the downhole hydraulic motor 28 to power the downhole hydraulic motor 28 and, thus, the drill bit 30. In certain embodiments, the return fluid 34 is returned uphole, and this flow back of return fluid 34 is controlled by suitable flow back equipment 58. In certain embodiments, the flow back equipment 58 may include chokes and other components/equipment used to control flow back of the return fluid 34 in a variety of applications, including well treatment applications.

As described in greater detail herein, the pump unit 56 and the flowback equipment 58 may include advanced sensors, actuators, and local controllers, such as PLCs, which may cooperate together to provide sensor data to, receive control signals from, and generate local control signals based on communications with, respectively, the surface processing system 42. In certain embodiments, as described in greater detail herein, the sensors may include flow rate, pressure, and fluid rheology sensors, among other types of sensors. In addition, as described in greater detail herein, the actuators may include actuators for pump and choke control of the pump unit 56 and the flowback equipment 58, respectively, among other types of actuators.

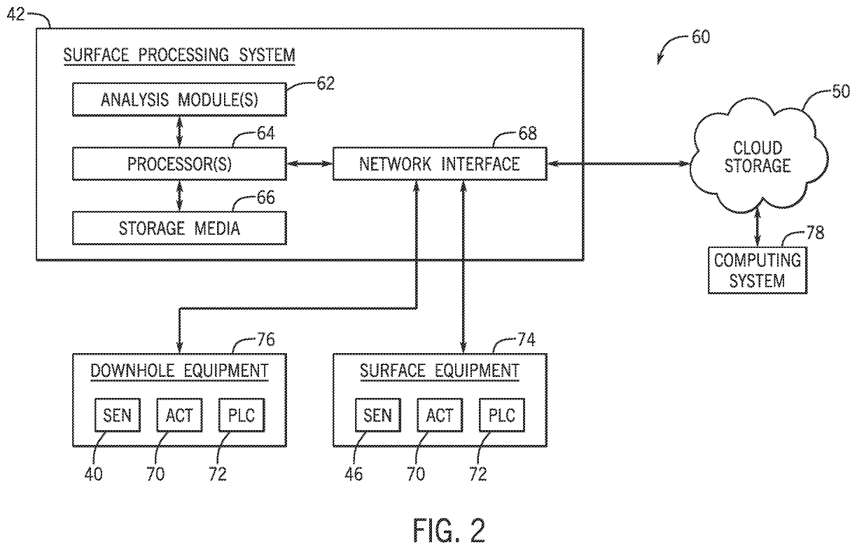

FIG. 2 illustrates a well control system 60 that may include the surface processing system 42 to control the coiled tubing system 10 described herein. In certain embodiments, the surface processing system 42 may include one or more analysis modules 62 (e.g., a program of computer-executable instructions and associated data) that may be configured to perform various functions of the embodiments described herein. In certain embodiments, to perform these various functions, an analysis module 62 executes on one or more processors 64 of the surface processing system 42, which may be connected to one or more storage media 66 of the surface processing system 42. Indeed, in certain embodiments, the one or more analysis modules 62 may be stored in the one or more storage media 66.

In certain embodiments, the one or more processors 64 may include a microprocessor, a microcontroller, a processor module or subsystem, a programmable integrated circuit, a programmable gate array, a digital signal processor (DSP), or another control or computing device. In certain embodiments, the one or more storage media 66 may be implemented as one or more non-transitory computer-readable or machine-readable storage media. In certain embodiments, the one or more storage media 66 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs); or other types of storage devices. Note that the computer-executable instructions and associated data of the analysis module(s) 62 may be provided on one computer-readable or machine-readable storage medium of the storage media 66, or alternatively, may be provided on multiple computer-readable or machine-readable storage media distributed in a large system having possibly plural nodes. Such computer-readable or machine-readable storage medium or media are considered to be part of an article (or article of manufacture), which may refer to any manufactured single component or multiple components. In certain embodiments, the one or more storage media 66 may be located either in the machine running the machine-readable instructions, or may be located at a remote site from which machine-readable instructions may be downloaded over a network for execution.

In certain embodiments, the processor(s) 64 may be connected to a network interface 68 of the surface processing system 42 to allow the surface processing system 42 to communicate with the various downhole sensors 40 and surface sensors 46 described herein, as well as communicate with the actuators 70 and/or PLCs 72 of the surface equipment 74 (e.g., the coiled tubing unit 52, the pump unit 56, the flowback equipment 58, and so forth) and of the downhole equipment 76 (e.g., the BHA 26, the downhole motor 28, the drill bit 30, the downhole well tool 36, and so forth) for the purpose of controlling operation of the coiled tubing system 10, as described in greater detail herein. In certain embodiments, the network interface 68 may also facilitate the surface processing system 42 to communicate data to cloud storage 50 (or other wired and/or wireless communication network) to, for example, archive the data or to enable external computing systems 78 to access the data and/or to remotely interact with the surface processing system 42.

It should be appreciated that the well control system 60 illustrated in FIG. 2 is only one example of a well control system, and that the well control system 60 may have more or fewer components than shown, may combine additional components not depicted in the embodiment of FIG. 2, and/or the well control system 60 may have a different configuration or arrangement of the components depicted in FIG. 2. In addition, the various components illustrated in FIG. 2 may be implemented in hardware, software, or a combination of both hardware and software, including one or more signal processing and/or application specific integrated circuits. Furthermore, the operations of the well control system 60 as described herein may be implemented by running one or more functional modules in an information processing apparatus such as application specific chips, such as application-specific integrated circuits (ASICs), field-programmable gate arrays (FPGAs), programmable logic devices (PLDs), systems on a chip (SOCs), or other appropriate devices. These modules, combinations of these modules, and/or their combination with hardware are all included within the scope of the embodiments described herein.

As described in greater detail herein, the embodiments described herein facilitate the operation of well-related tools. For example, a variety of data (e.g., downhole data and surface data) may be collected to enable optimization of operations of well-related tools such as the downhole well tool 36 illustrated in FIG. 1 by the surface processing system 42 illustrated in FIG. 2 (or other suitable processing system). In certain embodiments, the data may be provided as advisory data by the surface processing system 42 (or other suitable processing system). However, in other embodiments, the data may be used to facilitate automation of downhole processes and/or surface processes (i.e., the processes may be automated without human intervention), as described in greater detail herein, by the surface processing system 42 (or other suitable processing system). The embodiments described herein may enhance downhole operations by improving the efficiency and utilization of data to enable performance optimization and improved resource controls.

As described in greater detail herein, in certain embodiments, downhole parameters may be obtained via, for example, downhole sensors 40 while the downhole well tool 36 is disposed within the wellbore 14. In certain embodiments, the downhole parameters may be obtained in substantially real-time and sent to the surface processing system 42 via wired or wireless telemetry. In certain embodiments, downhole parameters may be combined with surface parameters by the surface processing system 42. In certain embodiments, the downhole and surface parameters may be processed by the surface processing system 42 during use of the downhole well tool 36 to enable automatic (e.g., without human intervention) optimization with respect to use of the downhole well tool 36 during subsequent stages of operation of the downhole well tool 36.

Examples of downhole parameters that may be sensed in real time include, but are not limited to, weight on bit (WOB), torque acting on the downhole well tool 36, downhole pressures, downhole differential pressures, and other desired downhole parameters. In certain embodiments, downhole parameters may be used by the surface processing system 42 in combination with surface parameters, and such surface parameters may include, but are not limited to, pump-related parameters (e.g., pump rate and circulating pressures of the pump unit 56). In certain embodiments, the surface parameters also may include parameters related to fluid returns (e.g., wellhead pressure, return fluid flow rate, choke settings, amount of proppant returned, and other desired surface parameters). In certain embodiments, the surface parameters also may include data from the coiled tubing unit 52 (e.g., surface weight of the coiled tubing string 12, speed of the coiled tubing 20, rate of penetration, and other desired parameters). In certain embodiments, the surface data that may be processed by the surface processing system 42 to optimize performance also may include previously recorded data such as fracturing data (e.g., close-in pressures from each fracturing stage, proppant data, friction data, fluid volume data, and other desired data).

In certain embodiments, depending on the type of downhole operation, the downhole data and surface data may be combined and processed by the surface processing system 42 to prevent stalls and to facilitate stall recovery with respect to the downhole well tool 36. In addition, in certain embodiments, processing of the downhole and surface data by the surface processing system 42 may also facilitate cooperative operation of the coiled tubing unit 52, the pump unit 56, the flowback equipment 58, and so forth. This cooperation provides synergy that facilitates output of advisory information and/or automation of the downhole process, as well as appropriate adjustment of the rate of penetration (ROP) and pump rates for each individual stage of the operation, by the surface processing system 42. It should be noted that the data (e.g., downhole data and surface data) also may be used by the surface processing system 42 to provide advisory information and/or automation of surface processes, such as pumping processes performed by the coiled tubing unit 52, the pump unit 56, the flowback equipment 58, and so forth.

In certain embodiments, use of this data enables the surface processing system 42 to self-learn to provide, for example, optimum downhole WOB and torque in an efficient manner. This real-time modeling by the surface processing system 42, based on the downhole and surface parameters, enables improved prediction of WOB, torque, and pressure differentials. Such modeling by the surface processing system 42 also enables the downhole process to be automated and automatically optimized by the surface processing system 42. The downhole parameters also may be used by the surface processing system 42 to predict wear on the downhole motor 28 and/or the drill bit 30, and to advise as to timing of the next trip to the surface for replacement of the downhole motor 28 and/or the drill bit 30.

The downhole parameters also enable use of pressures to be used by the surface processing system 42 in characterizing the reservoir 16. Such real-time downhole parameters also enable use of pressures by the surface processing system 42 for in situ evaluation and advisory of post-fracturing flow back parameters, and for creating an optimum flow back schedule for maximized production of, for example, hydrocarbon fluids from the surrounding reservoir 16. The data available from a given well may be utilized in designing the next fracturing schedule for the same pad/neighbor wells as well as predictions regarding subsequent wells.

For example, downhole data such as WOB, torque data from a load module associated with the downhole well tool 36, and bottom hole pressures (internal and external to the bottom hole assembly 26/downhole well tool 36) may be processed via the surface processing system 42. This processed data may then be employed by the surface processing system 42 to control the injector head 54 to generate, for example, a faster and more controlled rate of penetration (ROP). Additionally, the data may be updated by the surface processing system 42 as the downhole well tool 36 is moved to different positions along the wellbore 14 to help optimize operations. The data also enables automation of the downhole process through automated controls over the injector head 54 via control instructions provided by the surface processing system 42.

In certain embodiments, data from downhole may be combined by the surface processing system 42 with surface data received from injector head 54 and/or other measured or stored surface data. By way of example, surface data may include hanging weight of the coiled tubing string 12, speed of the coiled tubing 20, wellhead pressure, choke and flow back pressures, return pump rates, circulating pressures (e.g., circulating pressures from the manifold of a coiled tubing reel in the coiled tubing unit 52), and pump rates. The surface data may be combined with the downhole data by the surface processing system 42 with in real time to provide an automated system that self-controls the injector head 54. For example, the injector head 54 may be automatically controlled (e.g., without human intervention) to optimize ROP under direction from the surface processing system 42.

In certain embodiments, data from drilling parameters (e.g., surveys and pressures) as well as fracturing parameters (e.g., volumes and pressures) may be combined with real-time data obtained from sensors 40, 46. The combined data may be used by the surface processing system 42 in a manner that aids in machine learning (e.g., artificial intelligence) to automate subsequent jobs in the same well and/or for neighboring wells. The accurate combination of data and the updating of that data in real time helps the surface processing system 42 improve the automatic performance of subsequent tasks.

In certain embodiments, depending on the type of operation downhole, the surface processing system 42 may be programmed with a variety of algorithms and/or modeling techniques to achieve desired results. For example, the downhole data and surface data may be combined and at least some of the data may be updated in real time by the surface processing system 42. This updated data may be processed by the surface processing system 42 via suitable algorithms to enable automation and to improve the performance of, for example, downhole well tool 36. By way of example, the data may be processed and used by the surface processing system 42 for preventing motor stalls. In certain embodiments, downhole parameters such as forces, torque, and pressure differentials may be combined by the surface processing system 42 to enable prediction of a next stall of the downhole motor 28 and/or to give a warning to a supervisor. In such embodiments, the surface processing system 42 may be programmed to make self-adjustments (e.g., automatically, without human intervention) to, for example, speed of the injector head 54 and/or pump pressures to prevent the stall, and to ensure efficient continuous operation.

In addition, in certain embodiments, the data and the ongoing collection of data may be used by the surface processing system 42 to monitor various aspects of the performance of downhole motor 28. For example, motor wear may be detected by monitoring the effective torque of the downhole motor 28 based on data obtained regarding pump rates, pressure differentials, and actual torque measurements of the downhole well tool 36. Various algorithms may be used by the surface processing system 42 to help a supervisor on site to predict, for example, how many more hours the downhole motor 28 may be run efficiently. This data, and the appropriate processing of the data, may be used by the surface processing system 42 to make automatic decisions or to provide indications to a supervisor as to when to pull the coiled tubing string 12 to the surface to replace the downhole motor 28, the drill bit 30, or both, while avoiding unnecessary trips to the surface.

In certain embodiments, downhole data and surface data also may be processed via the surface processing system 42 to predict when the coiled tubing string 12 may become stuck. The ability to predict when the coiled tubing string 12 may become stuck helps avoid unnecessary short trips and, thus, improves coiled tubing pipe longevity. In certain embodiments, downhole parameters such as forces, torque, and pressure differentials in combination with surface parameters such as weight of the coiled tubing 20, speed of the coiled tubing 20, pump rate, and circulating pressure may be processed via the surface processing system 42 to provide predictions as to when the coiled tubing 20 will become stuck.

In certain embodiments, the surface processing system 42 may be designed to provide warnings to a supervisor and/or to self-adjust (e.g., automatically, without human intervention) either the speed of the injector head 54, the pump pressures and rates of the pump unit 56, or a combination of both, so as to prevent the coiled tubing 20 from getting stuck. By way of example, the warnings or other information may be output to a display of the surface processing system 42 to enable an operator to make better, more informed decisions regarding downhole or surface processes related to operation of the downhole well tool 36. In certain embodiments, the speed of the injector head 54 may be controlled via the surface processing system 42 by controlling the slack-off force from the surface. In general, the ability to predict and prevent the coiled tubing 20 from becoming stuck substantially improves the overall efficiency, and helps avoid unnecessary short trips if the probability of the coiled tubing 20 getting stuck is minimal. Accordingly, the downhole data and surface data may be used by the surface processing system 42 to provide advisory information and/or automation of surface processes, such as pumping processes or other processes.

Cleanout operations with coiled tubing 20 consists in pushing solid particles, such as sand or proppant from previous fracturing jobs, to the surface 24 by injecting fluids 32 though the lower end of the coiled tubing 20 (e.g., the BHA 26) next to where the solids lay in the wellbore 14. By supplying enough flow, the particles may remain suspended in the injected fluids 32 and be transported to the surface 24. The embodiments described herein automate coiled tubing operations using artificial intelligence (AI) planning, constraint satisfaction programming (CSP) and reinforcement learning (RL) on top of a heterogeneous collection of physics simulators. As used herein, the term “heterogeneous” may refer to various simulators that are focused on different sub-processes of coiled tubing operations, and which have varying sets of input parameters, output parameters, and so forth.

In order to design a cleanout job, engineers often use simulators that can model all the relevant physical phenomena occurring during such operations. Using such simulators, engineers investigate options such as pump rates, fluids to be pumped, coiled tubing movements that may provide optimum cleanout, and so forth. Options are also often constrained by certain events that should be prevented, or at least avoided when possible. Such events could be, for example, too much fluid leak-off into the reservoir, too much inflow from the reservoir, or too much friction between the coiled tubing and the casing. Other constraints may be related to the risk of damaging the coiled tubing by exposing it to too low or too high internal pressures. Some of the simulators are given explicit safety envelopes and generate failures when the envelopes are predicted to be breached, or the simulators adopt generic anomaly detection algorithms that trigger a failure if the observed state diverges from the expected state by a certain ratio α, as described in greater detail herein.

AI planning is a model-based technique for high-level modeling of real-world problems and, as such, it may be employed in automation systems that require powerful and explainable planning and execution automatically (e.g., without human interaction), such as space or deep-sea operations. While AI planning is very efficient at finding explainable optimal plans for logically complex problems, some of the non-linear dynamics of complex systems may require computational techniques for which AI planning is less efficient, or the access to the non-linear system may be limited such that the non-linear system may be treated as a blackbox.

Similar to AI planning, constraint satisfaction programming (CSP) paradigm builds up a model, which tends to be larger and less readable than AI planning models, but can more readily be scaled to modeling much larger problems, while maintaining the explainability. Alternatively, reinforcement learning (RL) builds models of domain experts, but provides less explanation for the behavior of the model. The problem of automating coiled tubing operations is relatively difficult based on the relative complexity of the modeling techniques, high levels of uncertainty, and strong emphasis on reliability. The embodiments described herein address these issues by tightly integrating coiled tubing operations, AI planning, CSP, and RL and execution in the oil and gas industry.

The embodiments described herein include coiled tubing simulators that capture decades of expertise and, as such, it is desirable to capture as much information as possible from the simulators themselves, formulating the problem of querying simulators optimally (e.g., maximizing confidence and efficiency) as a simulator graph search problem, as described in greater detail herein. Consequently, the representation for a simulator graph is built and integrated with AI planning, CSP, RL, and execution, which includes three main steps: (1) creation of a simulator graph that encodes the relations between inputs and outputs of different simulators, (2) integration of the simulator graph with an AI planner, CSP and RL, and (3) plan execution and monitoring of the plan with dynamic re-planning, as needed.

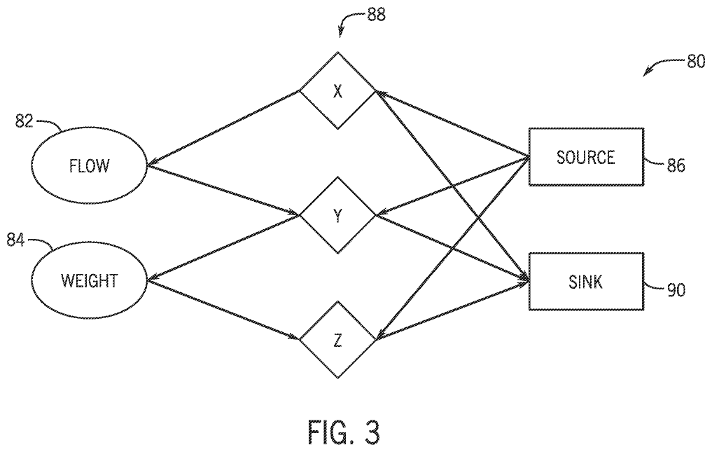

The coiled tubing environment (e.g., such as the coiled tubing system 10 illustrated in FIG. 1) is a relatively complex system with a multitude of subsystems that have been historically developed by different teams of experts based on the evolution of technologies within oil and gas industry. As such, various simulators relating to coiled tubing operations may be used in conjunction with each other in a heterogeneous manner, as described in greater detail herein. As illustrated in FIG. 3, a few non-limiting examples include a flow simulator 82 (e.g., to simulate pressures, temperatures, and flow rates of fluids into, through, and out of the wellbore 14 at various locations along the wellbore 14) and a weight simulator 84 (e.g., to simulate the weight of the coiled tubing 20, any downhole well tools 36 being conveyed downhole by the coiled tubing 20, and so forth, of the string at various locations along the wellbore 14). Other examples of simulators that may be used include a coil burst/collapse simulator (e.g., to simulate possibilities that the coiled tubing 20 will burst or collapse), a coil fatigue simulator (e.g., to simulate amounts and types of fatigue experienced by the coiled tubing 20), and other simulators that help ensure optimum performance of the coiled tubing operations described herein.

In certain embodiments, the flow simulator 82 may include inputs such as which fluids 32 are currently being injected into the wellbore 14 by the pump unit 56, know flow rates of these fluids 32 at certain locations (e.g., flow rates of the fluid 32 discharged from the pump unit 56, flow rates of the return fluid 34 received by the flowback equipment 58), pressure in the wellbore 14 at a given depth along the wellbore 14, speed of the coiled tubing 20, and certain static well parameters; and may generate outputs that include, for example, pressure at the lower end of the coiled tubing 20, return flow rates of water, oil, and gas (e.g., the return fluid 34), and other flow-related parameters of the coiled tubing operations described herein. In certain embodiments, the flow simulator model 82 may be transient and, as such, generally cannot be inverted (i.e., actions cannot be undone). Therefore, the flow of time should be simulated instead of jumping forward in discrete time steps.

In certain embodiments, the weight simulator 84 may include inputs such as surface weight of the coiled tubing 20 and the downhole well tool 36, back tension, stripper pressure, flow estimates, and certain static well parameters; and may generate outputs that include, for example, tension profile, predicted depth of the downhole well tool 36, friction coefficients, and so forth. As opposed to the flow simulator model 82, in certain embodiments, the weight simulator model 84 may be stateful and, therefore, the application of actions may be reversed, and jumping forward in discrete time steps may be possible.

Regardless of the specifics of the particular simulator, there are several features that are generally shared among all simulators. For example, the inputs of the simulators may often depend on the outputs of other simulators. For example, in certain embodiments, the weight simulator 84 may receive flow estimates produced by the flow simulator 82. In addition, certain simulators may also be run in different configurations, for example, receiving a particular variable as an input in a first configuration and predicting the value of that particular variable in a second configuration. In addition, certain simulators may provide confidence measures for each of its outputs. In addition, while certain simulators often take quite a bit of time to execute, in certain embodiments, they may be parameterized to execute faster at the cost of reducing confidence slightly in some of its outputs, where the function capturing the trade-off between confidence and speed varies between simulators.

Having a set of simulators with inputs and outputs that are represented by discrete and continuous variables, the state of the world s may be defined as the union of all the variables that appear in inputs and outputs of the simulators, and S to be the space of all possible states. Further, A may be defined to be a union of all actions that can be performed on the simulators. Additionally, for state s, a confidence function α: S→[0,1] may be defined, noted as s_{α} which associates a confidence level with each state variable in s. The confidence metric α indicates the certainty relating to a value of a state variable in state S_{α}, where confidence 0 represents that the value of the state variable is unknown, and confidence 1 represents that the value of the state variable is certain (e.g., at least within a relatively narrow range for the value, such as within 5%, within 3%, within 1%, or within even a smaller range).

In general, the simulators perform the function ρ: S×A→S, where either: (1) the current state s_{α′}=ρ(S_{α},λ) is estimated, where λ is an empty action and the confidence levels α′ are strictly higher than α, or (2) a future state s′_{α′}=ρ(S_{α}, α) is predicted, where s′_{α′} is a result of applying action α∈A. Often, computation of the ρ function is a performance bottleneck, but it is also a relatively important feature of the embodiments described herein. Generally, it would be preferable to compute ρ relatively fast, because doing so enables further exploration into the future and provides increased confidence in the predictions.

Identifying interactions between simulators is often one of the first steps. FIG. 3 illustrates an example simulator graph 80 with variables x, y, and z and two simulators—a flow simulator 82 and a weight simulator 84. Topological ordering of simulators 82, 84 then would be Flow, Weight. In the illustrated embodiment, the flow simulator 82 takes variable x as an input and produces variable y as an output, which is used as an input for the weight simulator 84, which produces variable z as an output. The simulator graph G=(V,E) may be used to identify interactions between simulators, where Vis a set of nodes, constructed in the following ways: (1) a source node 86, representing the input state S and the sink node S′, representing the output state, (2) a node 88 for each state variable, and (3) a node for each simulator 82, 84, exhaustively creating nodes for each possible combination of simulator configurations and confidence levels. In addition, E is a set of directed edges, labeled with costs and constructed in the following ways: (1) edges coming from the source node 86 to all state variable nodes 88, and from all state variable nodes 88 to the sink node 90, (2) an edge from a state variable node 88 to a simulator 82, 84 exists if the simulator 82, 84 takes the state variable as its input, and (3) an edge from a simulator 82, 84 to a state variable node 88 exists if the simulator 82, 84 produces the state variable as its output.

If it is assumed that the cost at the edges encodes a current metric for speed of computation and confidence in the results, optimal computation of p function is equivalent to finding a sub-graph G′ of minimal cost in graph G, such that nodes in G′ may be topologically ordered into a sequence of calls to the simulators. As described in greater detail herein, AI planning, CSP and RL are three different approaches that can be integrated with the simulator graph (e.g., the simulator graph 80 illustrated in FIG. 3) to generate a plan. Each of these approaches will be discussed separately.

### AI Planning

The planning problem may be defined as (V, A, I, G), where Vis a set of variables that define the space of all possible instances of the world (states); A is a set of actions, where preconditions and effects of each action are a partial assignment to the variables; I is the initial assignment to the variables; and G is the expected partial assignment to the variables (i.e., the planning goal). As described above, a simulator graph and the set of variables V for a planning problem is an extension of variables in the simulator graph, where causal variables (e.g., variables appearing in preconditions and effects of actions) may be added, which allow for encoding of the automation processes in a planning model. Similarly, the set of actions A is an extension of actions defined for the simulator graph, where the extra actions in the planning model fit various purposes, from modeling interactions with the human to modeling branching of different workflows provided by coiled tubing experts.

In certain embodiments, the planning problems may be solved by finding a plan π, which represents a set of actions scheduled in time such that starting from the initial state I and executing all the actions in x leads to the state G. Assuming a cost is associated with each action in A, then π* is an optimal plan if there does not exist a plan x with a lower sum of actions costs.

As described above, heterogeneous simulators may be optimally executed to predict effects of an action. In addition, optimal plans may lead to initial states turning into goal states—in coiled tubing practice, an optimal plan may be identified from the currently observed state of the world and the goal state, which may represent finishing a coiled tubing operation. The modeling of the planning problem may be done in a language such as planning domain definition language (PDDL) as but one non-limiting example. To completely integrate the simulator graph, the chosen planning system may be extended with, for example: (1) external state variables, which are not causally connected to the planning model, but their values restrict the plan space (e.g. variables indicating that certain boundary conditions have been met, and further planning is not possible), (2) custom search strategies, customizing search algorithms to consider behaviors of the simulators (e.g. not pruning search branches prematurely), and (3) custom heuristics, modeling pre-existing observed behavior (e.g. human operators solving the tasks). Once an optimal plan is obtained, it may be executed.

### Constraint Satisfaction Programming (CSP)

Constraint satisfaction programming is a technique on the edge between artificial intelligence and operations research. Its definition is very compact insofar as CSP=(X, D, C) is a constraint satisfaction problem such that: X={x₁, . . . , xₙ} is a set of variables, D={d₁, . . . , dₙ} is a set of their respective domains of values, discrete or continuous, C={c₁, . . . , cₘ} is a set of constraints on top the variables X, e.g. xᵢ+5<xⱼ, and a complete assignment is a function that assigns a value to each variable in X. In general, (X, D, C) is consistent if there exists an assignment a to X that satisfies all constraints C.

Similar to AI planning, CSP can act as a modeling language, in which a human modeler can capture domain expertise and, instead of generating a plan, CSP generates an assignment of values to decision variables. Modeling in CSP tends to have higher requirements on the modeler, having a slower learning curve and more control over the performance of the model than AI planning. CSP models are often generated programmatically, and they can be exceptionally large (millions of variables), compared to PDDL domains, which are human-readable and have relatively fast learning curves. Nevertheless, the level of control CSP provides, as well as the capability to efficiently handle continuous and discrete variables, gives it an edge in large-scale operations such as factory production planning or country-wide logistic scheduling. In general, CSP generates a plan, which is then passed to the execution flow, which is exactly the same as when using the AI planning modeling approach.

### Reinforcement Learning (RL)

Reinforcement learning builds upon recent advances in machine learning and deep neural networks. RL provides a few advantages over both AI planning and CSP methods. In both AI planning and CSP methods, the domain knowledge is generally captured manually in a domain specific language by an expert in those techniques. In contrast, using RL, a neural network learns the domain through exploration in a simulated environment. Providing a simulated environment with enough fidelity is a challenge for applying RL efficiently. As such, the simulated environment described herein is built from a set of heterogeneous simulators using a simulator graph.

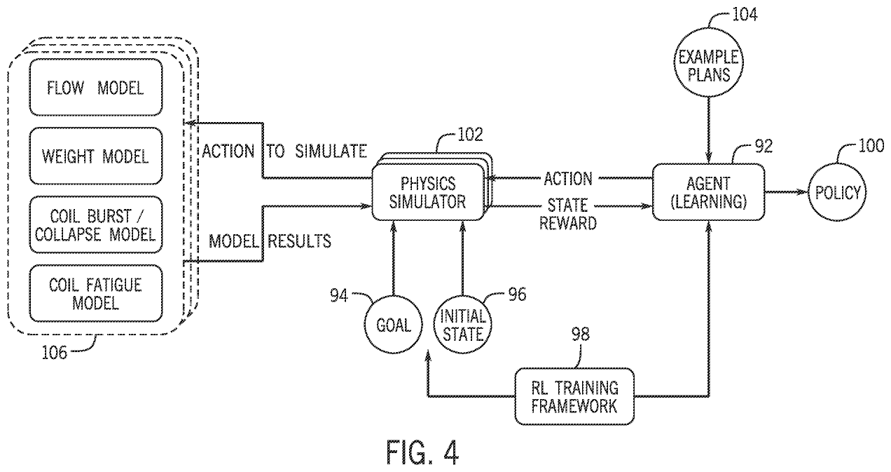

Training is the process where an RL agent learns the domain and chooses the most effective actions to achieve a particular goal. FIG. 4 illustrates example steps for training using RL. In general, the domain is learned through exploration of a simulated environment where thousands of attempts are made by an agent 92 to get to a goal state 94 from an initial state 96. On each attempt, it learns something new that improves the next attempt. As illustrated, in certain embodiments, an RL learning framework 98 may be chosen to coordinate the learning process. In general, the RL learning framework 98 orchestrates training of the agent 92. It contains the training policies and initiates training episodes. In certain situations, thousands of episodes may be run before a policy 100 is learned. The RL learning framework 98 decides when training of the agent 92 is completed, at which point the policy 100 is validated. Although illustrated in FIG. 4 as utilizing an RL learning framework 98, in other embodiments, an AI Planning framework, a CSP framework, of some combination of these three frameworks (or, even other types of frameworks) may be utilized.

As also illustrated in FIG. 4, in certain embodiments, the goal state 94 and initial state 96 may be provided to a physics simulator 102, and the physics simulator 102 may utilize the models and include additional information about the environment that is important for the agent 92 to learn. The environment may be set up to play a new episode automatically. The goal state 94 and initial state 96 are given for that particular environment. In certain embodiments, multiple environments with different goals and initial states may be created in parallel to accelerate and generalize learning.

As also illustrated in FIG. 4, in certain embodiments, the agent 92 may observe the current state and, based on a learning policy, choose a next action. It then may receive back an updated state and associated reward. The reward is used to learn the sequences of actions that were most effective in achieving the goal state 94, and is how the agent 92 is incentivized to get to the goal state 94. In general, the agent 92 learns how to navigate to the goal state 94 through both exploration and, optionally, also using example plans 104 generated by humans to accelerate initial exploration that tends to be somewhat random without a certain amount of guidance (e.g., imitation learning). The goal of the agent 92 is generally to maximize the accumulated reward. The learning is done through playing multiple episodes of simulations and learning to predict the reward/value of taking actions.

As also illustrated in FIG. 4, in certain embodiments, the physics simulator 102 may receive actions from the agent 92, simulate their execution, and update the state of the system accordingly. The physics simulator 102 also may calculate a reward for each action that is executed, the reward giving feedback to the agent 92 on the effectiveness of the action in getting closer to the goal state 94. In certain embodiments, multiple simulations may be run in parallel to accelerate the process. In certain embodiments, multiple instances of physics simulators 102 may be created to support parallel execution of simulations. Each instance is used to play through a complete episode, one action at a time.

Therefore, the models 106 (e.g., including the flow simulator 82 and the weight simulator 84 illustrated in FIG. 3) maintain their respective states so that they are ready to play through a next action chosen by the agent 92. Once the episode is completed, the model instance may be deleted. As such, the physics models 106 may be used to simulate the effect of certain actions. Unlike the AI planning method, the models 106 may maintain their state and simulate one action at a time.

In addition to orchestrating model execution and converting model results to states, the physics simulator 102 may also be responsible for calculating a reward for each action taken. The reward may be a function of the current state, the goal state 94, and other heuristics that may be fed back to the agent 92 if it takes actions in the right direction. In certain embodiments, the physics simulator 102 may also include rules and constraints not already captured by the models 106.

In general, the output of the training process is the agent 92 producing a policy 100 that can be used to generate plans. It should be noted that this process may be established at the engineering phase of an automation project. Once an agent 92 has been trained, it can be used to generate plans for multiple job scenarios without having to re-train it. However, it is also possible to do some of the training during execution, and have the agent 92 learn “at the wellsite” (e.g., while coiled tubing operations are being performed).

At the wellsite, at any time a plan needs to be created, the physics simulator 102 may be initialized with the latest estimated parameters and the agent 92 may be given the policy 100 learned in the previous step. The agent 100 may then play through one episode of the simulation, and the resulting sequence of actions may be a candidate for a plan. In certain embodiments, the agent 92 may play through a simulation so that a full plan can be inspected and approved by a human before it is dispatched to equipment for execution. However, in other embodiments, the agent 92 may regularly play through simulations while an approved plan is executed and, if a better plan is found (e.g., due to a more up-to-date state of the models 106), the operator may be notified. In addition, in certain embodiments, a full plan may be automatically executed by, for example, the surface processing system 42 sending appropriate control signals to the equipment of the coiled tubing system 10 described herein once an optimal plan is determined by the agent.

### Execution, Monitoring and Re-Planning

The optimistic execution of the plan is fairly straightforward. Actions in the plan may be sent for execution as soon as their preconditions are satisfied and their scheduled time arrives. However, in the real-world and coiled tubing domain (e.g., assuming not only optimistic execution), the actions may be monitored, execution failures may be handled and recovered from, and re-planning may be performed to achieve the goal from a different unexpected state.

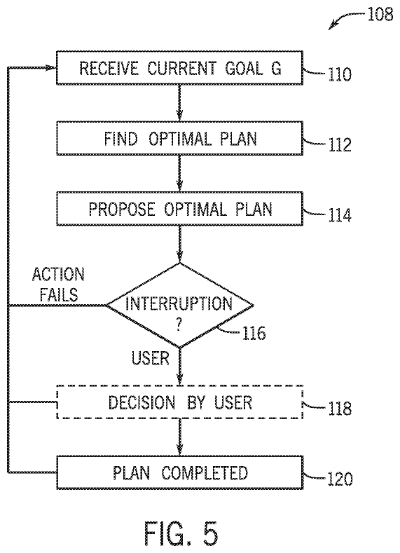

FIG. 5 illustrates an exemplary process 108 of executing, monitoring, and re-planning in accordance with the embodiments described herein. As described in greater detail herein, the surface processing system 42 may execute the steps of the process 108. First, a current goal G may be received (step 110). Next, an optimal plan may be found using an AI planner, CSP, or RL on top of the simulator graph for the problem (V, A, I, G), where I is the current state (step 112). Next, a plan π* may be proposed (e.g., to a user and/or artificial intelligence), and confirmation may be awaited (step 114). For example, in certain embodiments, a user may manually confirm. However, in other embodiments, artificial intelligence may automatically confirm. Next, the actions may continue executing according to the plan until interrupted by a failure (e.g., automatically when some necessary condition upon state space is not satisfied) or the user manually interrupts the plan (step 116). When an action fails, the process 108 continues back to step 110. However, if interrupted by a user, the process 108 may wait for a decision (step 118) and either resume or continue back to step 110. In other words, step 118 of the process 108 is optional, only occurring is a user interrupted the process 108. Next, the plan is completed (step 120), and the process 108 continues back to step 110.

These process steps represent simple and robust behavior for integration of AI Planning, CSP, RL, and execution. In scenarios where confidence at the end of the planning horizon (e.g., when a goal is achieved) is relatively low, the process 108 may be extended by continually re-planning from the current state at the background and, if a new better plan x is found, an evaluation may be made, either automatically by the surface processing system 42 or by a user, if is worth switching to the new alternative plan.

As such, the surface processing system 42 described herein may be configured to perform certain tasks including creating a simulator graph (e.g., the simulator graph 80 illustrated in FIG. 3) that encodes one or more relationships between inputs and outputs of a plurality of heterogeneous physics models (e.g., the models 106 illustrated in FIG. 4, including, for example, a flow simulator 82, a weight simulator 84, a coil burst/collapse simulator, a coil fatigue simulator, or some combination thereof) relating to running a downhole well tool 36 into a wellbore 14 via coiled tubing 20; integrating the simulator graph with one or more processing modules (e.g., one or more artificial intelligence planning modules, one or more constraint satisfaction programming modules, one or more reinforcement learning modules, or some combination thereof) configured to develop one or more plans (e.g., the plans 104 illustrated in FIG. 4) relating to running the downhole well tool 36 into the wellbore 14 via the coiled tubing 20; executing the one or more processing modules to develop the one or more plans relating to running the downhole well tool 36 into the wellbore 14 via the coiled tubing 20; and monitoring execution of the one or more plans relating to running the downhole well tool 36 into the wellbore 14 via the coiled tubing 20.

In certain embodiments, the surface processing system 42 described herein may also be configured to execute the one or more processing modules to develop one or more new plans during execution of the one or more plans relating to running the downhole well tool 36 into the wellbore 14 via the coiled tubing 20. In addition, in certain embodiments, the surface processing system 42 described herein may further be configured to train a reinforcement learning agent (e.g., the agent 92 illustrated in FIG. 4) to generate one or more policies (e.g., the policies 100 illustrated in FIG. 4) relating to the one or more plans by causing the reinforcement learning agent to generate a plurality of actions, to send the plurality of actions to a physics simulator (e.g., the physics simulator 102 illustrated in FIG. 4), to receive a plurality of state rewards from the physics simulator, and to use the plurality of state rewards to generate the one or more policies relating to the one or more plans. In addition, in certain embodiments, the surface processing system 42 described herein may also be configured to cause the physics simulator to receive an initial state (e.g., the initial state 96 illustrated in FIG. 4) and a goal state (e.g., the goal state 94 illustrated in FIG. 4), to receive the plurality of actions from the reinforcement learning agent, to send the plurality of actions to the plurality of heterogeneous physics models, to receive a plurality of model results from the plurality of heterogeneous physics models, and to generate the plurality of state rewards based at least in part on the plurality of model results.

The specific embodiments described above have been illustrated by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A method, comprising:
creating, via a processing system, a simulator graph that encodes one or more relationships between inputs and outputs of a plurality of heterogeneous physics models relating to running a downhole well tool into a wellbore via coiled tubing;
integrating, via the processing system, the simulator graph with one or more processing modules configured to develop one or more plans relating to running the downhole well tool into the wellbore via the coiled tubing;
executing, via the processing system, the one or more processing modules to develop the one or more plans relating to running the downhole well tool into the wellbore via the coiled tubing; and
monitoring, via the processing system, execution of the one or more plans relating to running the downhole well tool into the wellbore via the coiled tubing.

2. The method of claim 1, wherein the one or more processing modules comprise one or more artificial intelligence planning modules, one or more constraint satisfaction programming modules, one or more reinforcement learning modules, or some combination thereof.

3. The method of claim 1, comprising executing, via the processing system, the one or more processing modules to develop one or more new plans during execution of the one or more plans relating to running the downhole well tool into the wellbore via the coiled tubing.

4. The method of claim 1, comprising training, via the processing system, a reinforcement learning agent to generate one or more policies relating to the one or more plans by causing the reinforcement learning agent to:
generate a plurality of actions;
send the plurality of actions to a physics simulator;
receive a plurality of state rewards from the physics simulator; and
use the plurality of state rewards to generate the one or more policies relating to the one or more plans.

5. The method of claim 4, comprising causing, via the processing system, the physics simulator to:
receive an initial state and a goal state;
receive the plurality of actions from the reinforcement learning agent;
send the plurality of actions to the plurality of heterogeneous physics models;
receive a plurality of model results from the plurality of heterogeneous physics models; and
generate the plurality of state rewards based at least in part on the plurality of model results.

6. The method of claim 1, wherein the plurality of heterogeneous physics models comprise a flow simulator.

7. The method of claim 1, wherein the plurality of heterogeneous physics models comprise a weight simulator.

8. The method of claim 1, wherein the plurality of heterogeneous physics models comprise a coil burst/collapse simulator.

9. The method of claim 1, wherein the plurality of heterogeneous physics models comprise a coil fatigue simulator.

10. A tangible non-transitory computer-readable media comprising process-executable instructions that, when executed by one or more processors, cause the one or more processors to:
create a simulator graph that encodes one or more relationships between inputs and outputs of a plurality of heterogeneous physics models relating to running a downhole well tool into a wellbore via coiled tubing;
integrate the simulator graph with one or more processing modules configured to develop one or more plans relating to running the downhole well tool into the wellbore via the coiled tubing;
execute the one or more processing modules to develop the one or more plans relating to running the downhole well tool into the wellbore via the coiled tubing; and
monitor execution of the one or more plans relating to running the downhole well tool into the wellbore via the coiled tubing.

11. The tangible non-transitory computer-readable media of claim 10, wherein the one or more processing modules comprise one or more artificial intelligence planning modules, one or more constraint satisfaction programming modules, one or more reinforcement learning modules, or some combination thereof.

12. The tangible non-transitory computer-readable media of claim 10, wherein the process-executable instructions, when executed by one or more processors, cause the one or more processors to execute the one or more processing modules to develop one or more new plans during execution of the one or more plans relating to running the downhole well tool into the wellbore via the coiled tubing.

13. The tangible non-transitory computer-readable media of claim 10, wherein the process-executable instructions, when executed by one or more processors, cause the one or more processors to train a reinforcement learning agent to generate one or more policies relating to the one or more plans by causing the reinforcement learning agent to:
generate a plurality of actions;
send the plurality of actions to a physics simulator;
receive a plurality of state rewards from the physics simulator; and
use the plurality of state rewards to generate the one or more policies relating to the one or more plans.

14. The tangible non-transitory computer-readable media of claim 13, wherein the process-executable instructions, when executed by one or more processors, cause the one or more processors to cause the physics simulator to:
receive an initial state and a goal state;
receive the plurality of actions from the reinforcement learning agent;
send the plurality of actions to the plurality of heterogeneous physics models;
receive a plurality of model results from the plurality of heterogeneous physics models; and
generate the plurality of state rewards based at least in part on the plurality of model results.

15. The tangible non-transitory computer-readable media of claim 10, wherein the plurality of heterogeneous physics models comprise a flow simulator.

16. The tangible non-transitory computer-readable media of claim 10, wherein the plurality of heterogeneous physics models comprise a weight simulator.

17. The tangible non-transitory computer-readable media of claim 10, wherein the plurality of heterogeneous physics models comprise a coil burst/collapse simulator.

18. The tangible non-transitory computer-readable media of claim 10, wherein the plurality of heterogeneous physics models comprise a coil fatigue simulator.

19. A system, comprising:
a surface processing system configured to:
create a simulator graph that encodes one or more relationships between inputs and outputs of a plurality of heterogeneous physics models relating to running a downhole well tool into a wellbore via coiled tubing;
integrate the simulator graph with one or more processing modules configured to develop one or more plans relating to running the downhole well tool into the wellbore via the coiled tubing;
execute the one or more processing modules to develop the one or more plans relating to running the downhole well tool into the wellbore via the coiled tubing; and
monitor execution of the one or more plans relating to running the downhole well tool into the wellbore via the coiled tubing.
wherein the plurality of heterogeneous physics models comprise a flow simulator, a weight simulator, a coil burst/collapse simulator, a coil fatigue simulator, or some combination thereof.
